(19) United States
(12) Patent Application Publication
(10) Pub. No.: US 2025/0056891 A1
(43) Pub. Date: Feb. 13, 2025

(54) ARRAY SUBSTRATE, DISPLAY PANEL, AND DISPLAY APPARATUS

(71) Applicant: Xiamen Tianma Microelectronics Co., Ltd., Xiamen (CN)

(72) Inventors: Yiqiang LIN, Xiamen (CN); Dongxu QIU, Xiamen (CN); Wei WU, Xiamen (CN); Hao WU, Xiamen (CN)

(21) Appl. No.: 18/931,103

(22) Filed: Oct. 30, 2024

(30) Foreign Application Priority Data
Apr. 2, 2024 (CN) 202410397748.3

(51) Int. Cl. H01L 27/12

(52) U.S. Cl. CPC H01L 27/1244

(57) ABSTRACT

An array substrate, a display panel and a display apparatus. The array substrate includes a base. The base includes a non-display region and a display region. The non-display region includes a first non-display region and a second non-display region. The second non-display region includes a wiring region and an aperture. The wiring region surrounds the aperture. The display region surrounds the wiring region. The aperture includes first side, second side, third side and fourth side. The wiring region includes signal lines. The signal lines include connecting lines surrounding an edge of the aperture. The signal lines includes first signal lines and second signal lines. The first signal line includes a first connecting line. The second signal line includes a second connecting line. Along the first direction, the first connecting line is adjacent to the first side, and the second connecting line is adjacent to the second side.

### CROSS-REFERENCE TO RELATED APPLICATION

The present application claims priority to Chinese Patent Application No. 202410397748.3, filed on Apr. 2, 2024, the content of which is incorporated herein by reference in its entirety.

### TECHNICAL FIELD

The present disclosure relates to the field of display technologies, and in particular to an array substrate, a display panel, and a display apparatus.

### BACKGROUND

With rapid development of narrow borders of display screens, a full screen emerges. Since the full screen is generally provided with a front camera, a speaker, an indicator lamp, a sensor, and the like, an aperture is required to be formed in a display region of the full screen. However, the full screen is prone to an obvious bright line in the display region, resulting in non-uniform display. Especially, when a diameter or a length of the aperture is increased, this phenomenon is more evident.

Therefore, how to provide an array substrate, a display panel, and a display apparatus to solve the bright line in the display region is a big technical problem to be solved urgently by those skilled in the art.

### SUMMARY

In an aspect, embodiments of the present disclosure provide an array substrate. The array substrate includes a base. The base includes a non-display region and a display region. The non-display region includes a first non-display region and a second non-display region. The first non-display region surrounds the display region. The display region surrounds the second non-display region. The second non-display region includes a wiring region and an aperture. The wiring region surrounds the aperture. The display region surrounds the wiring region. The aperture includes a first side and a second side opposite to each other along a first direction, and a third side and a fourth side opposite to each other along a second direction; and the first direction intersects with the second direction. The wiring region includes a plurality of signal lines. One of the plurality of signal lines includes connecting lines surrounding an edge of the aperture. The plurality of signal lines includes first signal lines and second signal lines. The first signal line includes a first connecting line. The second signal line includes a second connecting line. Along the first direction, the first connecting line is adjacent to the first side, and the second connecting line is adjacent to the second side. The first connecting line and/or the second connecting line include a compensating line. The compensating line of the first connecting line is immediately adjacent to the second connecting line, and/or the compensating line of the second connecting line is immediately adjacent to the first connecting line.

In another aspect, embodiments of the present disclosure provide a display panel. The display panel includes an array substrate. The array substrate includes a base. The base includes a non-display region and a display region. The non-display region includes a first non-display region and a second non-display region. The first non-display region surrounds the display region. The display region surrounds the second non-display region. The second non-display region includes a wiring region and an aperture. The wiring region surrounds the aperture. The display region surrounds the wiring region. The aperture includes a first side and a second side opposite to each other along a first direction, and a third side and a fourth side opposite to each other along a second direction; and the first direction intersects with the second direction. The wiring region includes a plurality of signal lines. One of the plurality of signal lines includes connecting lines surrounding an edge of the aperture. The plurality of signal lines includes first signal lines and second signal lines. The first signal line includes a first connecting line. The second signal line includes a second connecting line. Along the first direction, the first connecting line is adjacent to the first side, and the second connecting line is adjacent to the second side. The first connecting line and/or the second connecting line include a compensating line. The compensating line of the first connecting line is immediately adjacent to the second connecting line, and/or the compensating line of the second connecting line is immediately adjacent to the first connecting line.

In a still another aspect, embodiments of the present disclosure provide a display apparatus. The display apparatus includes a display panel. The display panel includes an array substrate. The array substrate includes a base. The base includes a non-display region and a display region. The non-display region includes a first non-display region and a second non-display region. The first non-display region surrounds the display region. The display region surrounds the second non-display region. The second non-display region includes a wiring region and an aperture. The wiring region surrounds the aperture. The display region surrounds the wiring region. The aperture includes a first side and a second side opposite to each other along a first direction, and a third side and a fourth side opposite to each other along a second direction; and the first direction intersects with the second direction. The wiring region includes a plurality of signal lines. One of the plurality of signal lines includes connecting lines surrounding an edge of the aperture. The plurality of signal lines includes first signal lines and second signal lines. The first signal line includes a first connecting line. The second signal line includes a second connecting line. Along the first direction, the first connecting line is adjacent to the first side, and the second connecting line is adjacent to the second side. The first connecting line and/or the second connecting line include a compensating line. The compensating line of the first connecting line is immediately adjacent to the second connecting line, and/or the compensating line of the second connecting line is immediately adjacent to the first connecting line.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may further be obtained based on these drawings.

FIG. 1 is a schematic view of an array substrate in the related art;

FIG. 2 is a schematic view of an array substrate according to an embodiment of the present disclosure;

FIG. 3A is a partially enlarged view of the embodiment shown in FIG. 2 according to another embodiment of the present disclosure;

FIG. 3B is a partial schematic view of an array substrate according to an embodiment of the present disclosure;

FIG. 3C is a partial schematic view of an array substrate according to another embodiment of the present disclosure;

FIG. 3D is a partial schematic view of an array substrate according to another embodiment of the present disclosure;

FIG. 4A is a partial schematic view of an array substrate according to another embodiment of the present disclosure;

FIG. 4B is a partial schematic view of an array substrate according to another embodiment of the present disclosure;

FIG. 5A is a partial schematic view of an array substrate according to another embodiment of the present disclosure;

FIG. 5B is a partial schematic view of an array substrate according to another embodiment of the present disclosure;

FIG. 5C is a partial schematic view of an array substrate according to another embodiment of the present disclosure;

FIG. 5D is a partial schematic view of an array substrate according to another embodiment of the present disclosure;

FIG. 5E is a schematic sectional view along a line A-A′ shown in FIG. 5A, a line B-B′ shown in FIG. 5B, a line C-C′ shown in FIG. 5C, and a line D-D′ shown in FIG. 5D according to an embodiment of the present disclosure;

FIG. 5F is another schematic sectional view along a line A-A′ shown in FIG. 5A, a line B-B′ shown in FIG. 5B, a line C-C′ shown in FIG. 5C, and a line D-D′ shown in FIG. 5D according to an embodiment of the present disclosure;

FIG. 6A is a partial schematic view of an array substrate according to another embodiment of the present disclosure;

FIG. 6B is a partial schematic view of an array substrate according to another embodiment of the present disclosure;

FIG. 6C is a partial schematic view of an array substrate according to another embodiment of the present disclosure;

FIG. 6D is a partial schematic view of an array substrate according to another embodiment of the present disclosure;

FIG. 7A is a partial schematic view of an array substrate according to another embodiment of the present disclosure;

FIG. 7B is a partial schematic view of an array substrate according to another embodiment of the present disclosure;

FIG. 7C is a partial schematic view of an array substrate according to another embodiment of the present disclosure;

FIG. 7D is a partial schematic view of an array substrate according to another embodiment of the present disclosure;

FIG. 7E is a schematic sectional view along a line E-E′ shown in FIG. 7A, a line H-H′ shown in FIG. 8A, and a line I-I′ shown in FIG. 8A according to an embodiment of the present disclosure;

FIG. 7F is another schematic sectional view along a line E-E′ shown in FIG. 7A, a line H-H′ shown in FIG. 8A, and a line I-I′ shown in FIG. 8A according to an embodiment of the present disclosure;

FIG. 7G is a schematic sectional view along a line F-F′ shown in FIG. 7A according to another embodiment of the present disclosure;

FIG. 8A is a partial schematic view of an array substrate according to another embodiment of the present disclosure;

FIG. 8B is a partial schematic view of an array substrate according to another embodiment of the present disclosure;

FIG. 9A is a partial schematic view of an array substrate according to another embodiment of the present disclosure;

FIG. 9B is a partial schematic view of an array substrate according to another embodiment of the present disclosure;

FIG. 9C is a schematic sectional view along a line J-J′ shown in FIG. 9A, a line K-K′ shown in FIG. 10, and a line L-L′ shown in FIG. 10 according to an embodiment of the present disclosure;

FIG. 9D is another schematic sectional view along a line J-J′ shown in FIG. 9A, a line K-K′ shown in FIG. 10, and a line L-L′ shown in FIG. 10 according to an embodiment of the present disclosure;

FIG. 10 is a partial schematic view of an array substrate according to another embodiment of the present disclosure;

FIG. 11 is a schematic view of a display apparatus according to an embodiment of the present disclosure;

FIG. 12 is a schematic view of a display apparatus according to another embodiment of the present disclosure; and

FIG. 13 is a schematic view of a display apparatus according to another embodiment of the present disclosure.

### DESCRIPTION OF EMBODIMENTS

The technical solutions of the embodiments of the present disclosure are clearly and completely described below with reference to the drawings in the embodiments of the present disclosure. The described embodiments are merely a part rather than all embodiments of the present disclosure. All other embodiments derived by those of ordinary skill in the art based on the embodiments of the present disclosure shall fall within the protection scope of the present disclosure.

Each embodiment in the description is described in a progressive mode, each embodiment focuses on differences from other embodiments, and references can be made to each other for the same and similar parts between embodiments. Since an apparatus disclosed in the embodiments corresponds to a method disclosed in the embodiments, its description is relatively simple, and reference can be made to description of the method for relevant contents.

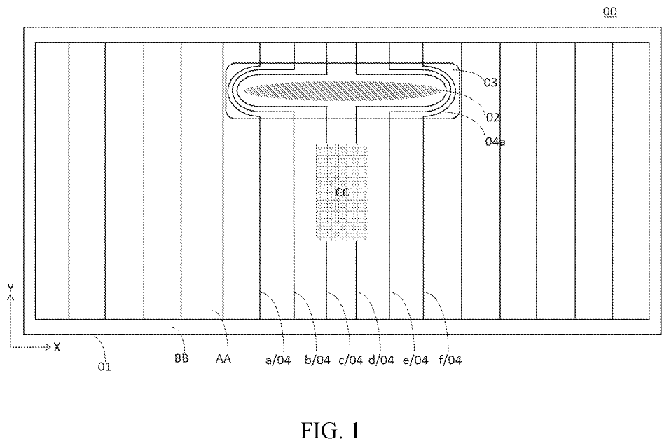

FIG. 1 is a schematic view of an array substrate in the related art. As shown in FIG. 1, the array substrate 00 includes a base 01. The base 01 includes a display region AA and a non-display region BB. The non-display region BB surrounds the display region AA. An aperture 02 is formed in the display region AA. A wiring region 03 is provided around the aperture 02. The display region AA surrounds the wiring region 03. In addition, the array substrate 00 further includes sub-pixels (not shown in the drawing) provided in an array in the display region AA.

Multiple signal lines 04 are provided in the display region AA. Multiple signal lines 04 are provided along a direction X and extend along a direction Y. The direction X intersects with the direction Y. In a related art, the direction X is perpendicular to the direction Y. A plane formed by the direction X and the direction Y is parallel to a plane of the array substrate 00. Multiple signal lines 04 run through from one terminal of the display region AA to the other terminal of the display region AA along the direction Y. The signal lines 04 each are electrically connected to one column of pixels (not shown in the drawing). As shown in FIG. 1, the signal lines 04 running through the wiring region 03 include a signal line a, a signal line b, a signal line c, a signal line d, a signal line e, and a signal line f. The signal line a, the signal line b, the signal line c, the signal line d, the signal line e and the signal line f each include a connecting line 04a in the wiring region 03. Along the first direction X, the connecting line 04a of each of the signal line a, the signal line b and the signal line c is provided at one side of the aperture 02, while the connecting line 04a of each of the signal line d, the signal line e and the signal line f is provided at the other side of the aperture 02. When the array substrate 00 operates, a bright line easily appears in a central region of the display region AA, namely a region CC shown by FIG. 1, to cause non-uniform display.

In the structure of the array substrate provided in the related art, since the signal line c and the signal line d are adjacent to the aperture 02, the connecting line 04a of each of the signal line c and the signal line d in the wiring region 03 only includes one side immediately adjacent to the connecting line 04a of each of the signal line b and the signal line e. The connecting line 04a of each of the signal line a and the signal line b and the connecting line 04a of each of the signal line e and the signal line f include two sides immediately adjacent to the connecting line (the connecting line 04a of each of the signal line a and the signal line f includes one side immediately adjacent to the signal line 04 in the normal region AA).

With reference to an equation C=εS/4πkd for calculating the capacitance, while the dielectric constant ε of an electrode plate of a capacitor, the static constant k and the distance d between the electrode plates are unchanged, the capacitance C is directly proportional to an overlapping area S between the electrode plates. In the equation, the overlapping area between the electrode plates is the same as an overlapping area for a projection of the signal lines 04 in a direction perpendicular to a plane of paper (namely an area mutually overlapped by sides of the signal lines 04).

Since the connecting line 04a of each of the signal line c and the signal line d only includes one side immediately adjacent to other connecting lines 04a, an overlapping area S of the connecting line 04a of each of the signal line c and the signal line d with the other connecting line 04a is only a half of an overlapping area of each of the other connecting lines 04a, and a coupling capacitance C of the connecting line 04a of each of the signal line c and the signal line d is only a half of a coupling capacitance of each of the other connecting line 04a. Consequently, the coupling capacitance of the signal line c and the coupling capacitance of the signal line d are lower than the coupling capacitances of the other connecting line 04.

The following descriptions are made to a process for generating the bright line in the region CC due to the low coupling capacitance of the signal line c and the low coupling capacitance of the signal line d.

It is assumed that the signal line 04 is a data signal line, the signal line a charges a first column of sub-pixels, the signal line b charges a second column of sub-pixels, the signal line c charges a third column of sub-pixels, the signal line d charges a fourth column of sub-pixels, the signal line e charges a fifth column of sub-pixels, and the signal line f charges a sixth column of sub-pixels. Usually, a signal transmitted by the signal line a and a signal transmitted by the signal line c have a same polarity, which is positive and is represented by a symbol “+”. A polarity of a signal transmitted by the signal line b is reverse to the polarity of the signal transmitted by the signal line a, is negative, and is represented by a symbol “−”. In actual operation, the signal line a charges the first column of sub-pixels, until voltages of the sub-pixels on the first column are the same as a preset voltage. The signal line b charges the second column of sub-pixels. Due to the coupling capacitance between the signal line a and the signal line b, a signal jump appears when the second column of sub-pixels are charged, thus pulling down the voltages of the sub-pixels on the first column. Meanwhile, since at least one of voltages of the sub-pixels on the second column is jumped to the first column of sub-pixels, the voltages of the sub-pixels on the second column are also pulled down. Likewise, the signal line c charges the third column of sub-pixels. Due to the coupling capacitance between the signal line b and the signal line c, a signal jump appears when the third column of sub-pixels are charged, thus pulling down the voltages of the sub-pixels on the second column again. Meanwhile, voltages of the sub-pixels on the third column are also pulled down. The signal line d charges the fourth column of sub-pixels. Since the connecting line 04a of the signal line d and the connecting line 04a of the signal line c are far away from each other (respectively located at two sides of the aperture), the coupling capacitance cannot be formed. In charging of the signal line d, voltages of the sub-pixels on the third column are pulled down little. Likewise, voltages of the sub-pixels on the fourth column are also pulled down little. In this way, two sides of each of the signal line a, the signal line b, the signal line e and the signal line f generate the coupling capacitance, and an actual voltage received by the columns of sub-pixels respectively electrically connected to the signal line a, the signal line b, the signal line e and the signal line f is the same as a voltage in normal display. However, an actual voltage received by the signal line c and the signal line d is greater than the voltage in the normal display. Hence, the columns of sub-pixels respectively electrically connected to the signal line c and the signal line d are brighter than other columns of sub-pixels, and the bright line appears in the region CC to cause the non-uniform display.

It is assumed that the signal line is a scanning signal line. Unlike the data signal line, the scanning signal line sequentially charges the electrically connected columns of sub- pixels. For example, the signal line in scanning charges the signal line a. The signal line a receives a high-level signal. A normal scanning line adjacent to the signal line a in the region AA and the signal b have a low-level signal. Hence, left and right sides of the signal line a have the coupling capacitance. Likewise, when the signal line b is scanned, the signal line b receives a high-level signal. The signal line a and the signal c receives a low-level signal. The left and right sides of the signal line a also have the coupling capacitance. When the signal line c or the signal line d is scanned, the coupling capacitance is formed only at one side of the signal line c or the signal line d. A voltage signal received by the signal line c or the signal line d is higher than voltage signals received by other signal lines, the column of pixels electrically connected to the signal line c or the signal line d have a higher data voltage than data voltages on other columns of pixels, and the bright line also appears in the region CC.

In view of this, in order to make coupling capacitances of the signal lines more uniform, improvements are made to the structure of the array substrate. The connecting line adjacent to an edge of the aperture is provided with a compensating line. The compensating line of the signal line at one side of the aperture is immediately adjacent to the connecting line of the signal line at the other side of the aperture, such that the compensating line of the signal line at one side of the aperture and the connecting line of the signal line at the other side of the aperture compensate a capacitance to each other. This improves the coupling capacitance of the signal line immediately adjacent to the edge of the aperture, makes the coupling capacitances of the signal lines in the display region more uniform, thereby solving the bright line.

The present disclosure provides an array substrate, and further provides a display panel. The display panel includes the array substrate provided by the present disclosure. The display panel provided by the present disclosure may be an organic light-emitting diode (OLED) panel, a Micro-LED display panel, a Mini-LED display panel or a liquid crystal display (LCD) panel, and is not particularly defined in the present disclosure. When the display panel is the LCD panel, the display panel further includes an opposed substrate, and a liquid crystal molecular layer between the array substrate and the opposed substrate. The opposed substrate includes a black matrix (BM) and a color film. The color film includes a red color filter, a green color filter, and a blue color filter. The BM defines multiple sub-pixels. The sub-pixels each include one color filter. In an embodiment of the present disclosure, the color film may further include a white color filter. The present disclosure further provides the display apparatus, including the display panel provided by the present disclosure.

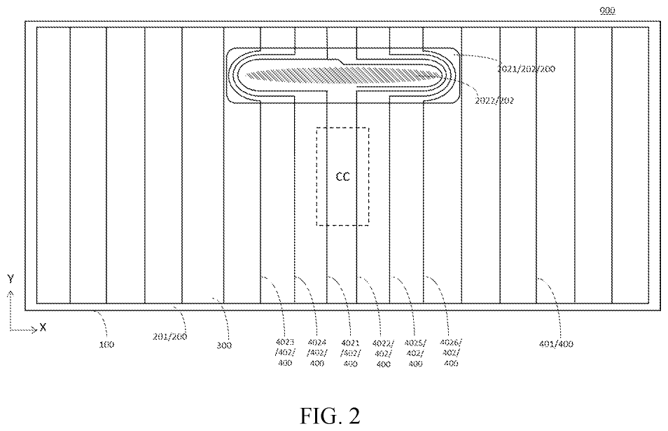

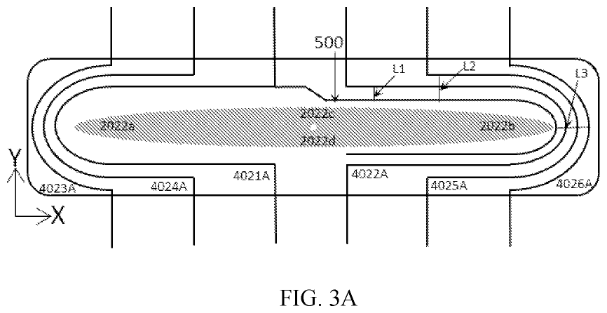

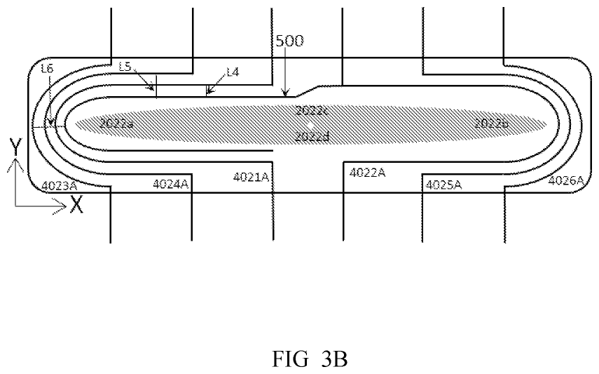

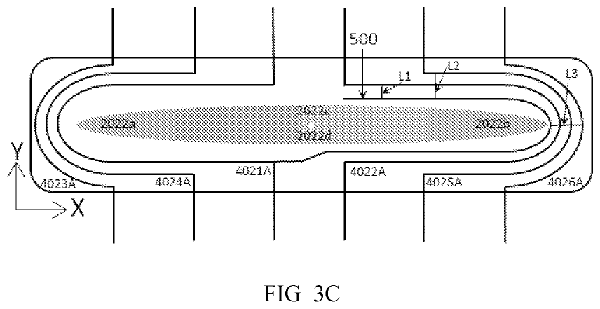

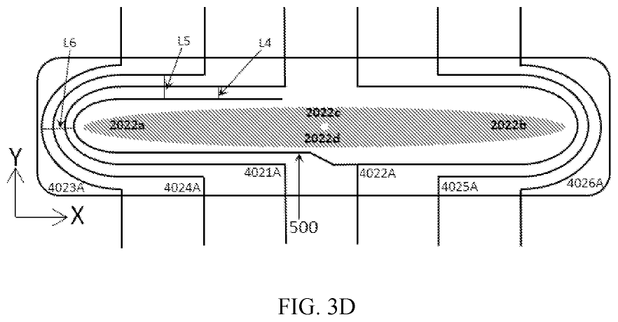

FIG. 2 is a schematic view of an array substrate according to an embodiment of the present disclosure. FIG. 3A is a partially enlarged view of the embodiment shown in FIG. 2. Referring to FIG. 2 and FIG. 3A, the array substrate 000 includes a base 100. The base 100 includes a non-display region 200 and a display region 300. The non-display region includes a first non-display region 201 and a second non-display region 202. The first non-display region 201 is a border region of the array substrate 000. The first non-display region 201 surrounds the display region 300. The display region 300 surrounds the second non-display region 202. The second non-display region includes a wiring region 2021 and an aperture 2022. The wiring region 2021 surrounds the aperture 2022. Referring to FIG. 3A, the aperture 2022 includes a first side 2022a and a second side 2022b opposite to each other along a first direction X, as well as a third side 2022c and a fourth side 2022d opposite to each other along a second direction Y. The first direction X intersects with the second direction Y. In the present disclosure, the first direction X is perpendicular to the second direction Y. The aperture 2022 may be a via hole penetrating through the array substrate 000 along a thickness direction of the array substrate 000, and may also be a blind hole formed only by excavating at least one of preset film layers on the array substrate 000.

In the embodiment, multiple signal lines 400 are provided in the display region 300. The signal lines 400 each may be a data line for providing a writing voltage for sub-pixels, and may also be a scanning line for providing a switching signal for a thin-film transistor (TFT) electrically connected to the sub-pixels. In the present disclosure, a case where the signal line 400 is the data line is used as an example for description. Principles revealed in the present disclosure are also applicable to the scanning line. In the embodiment, multiple scanning lines (not shown in the drawing) and multiple signal lines 400 (data lines) define multiple sub-pixels (not shown in the drawing). A same column of sub-pixels is electrically connected to a same one of the signal lines 400.

The signal lines 400 include multiple signal lines 401 in the normal display region and multiple signal lines 402 penetrating through the wiring region. Voltages received by two adjacent signal lines have opposite polarities. FIG. 2 takes a case where six signal lines 402 pass through the wiring region 2021 as an example for description, but is not limited to the six signal lines 402. In an embodiment of the present disclosure, there may be eight, ten, twelve or more signal lines 402 according to a size or other parameters of the aperture. In order to achieve uniform display, a number of the signal lines 402 is preferably an even number, but is not merely limited to the even number. As shown in FIG. 2 and FIG. 3, the signal lines 402 include a first signal line 4021 and a second signal line 4022. The first signal line 4021 includes a first connecting line 4021A in the wiring region 2021. The second signal line 4022 includes a second connecting line 4022A in the wiring region 2021. In an embodiment of the present disclosure, the signal lines 402 further include a third signal line 4023, a fourth signal line 4024, a fifth signal line 4025, and a sixth signal line 4026. The third signal line 4023 includes a third connecting line 4023A in the wiring region 2021. The fourth signal line 4024 includes a fourth connecting line 4024A in the wiring region 2021. The fifth signal line 4025 includes a fifth connecting line 4025A in the wiring region 2021, and the sixth signal line 4026 includes a sixth connecting line 4026A in the wiring region 2021. Along the first direction X, the first connecting line 4021A, the third connecting line 4023A and the fourth connecting line 4024A are adjacent to the first side 2022a of the aperture 2022, and the second connecting line 4022A, the fifth connecting line 4025A and the sixth connecting line 4026A are adjacent to the second side 2022b of the aperture 2022. Along the first direction X, the first connecting line 4021A and the second connecting line 4022A are respectively adjacent to the first side 2022a of the aperture 2022 and the second side 2022b of the aperture 2022. The third connecting line 4023 A is provided at a side of the first connecting line 4021A away from the first side 2022a of the aperture 2022. The sixth connecting line 4026A is provided at a side of the second connecting line 4022A away from the second side 2022b of the aperture 2022. The fourth connecting line 4024A is provided between the first connecting line 4021A and the third connecting line 4023A. The fifth connecting line 4025A is provided between the second connecting line 4022A and the sixth connecting line 4026A.

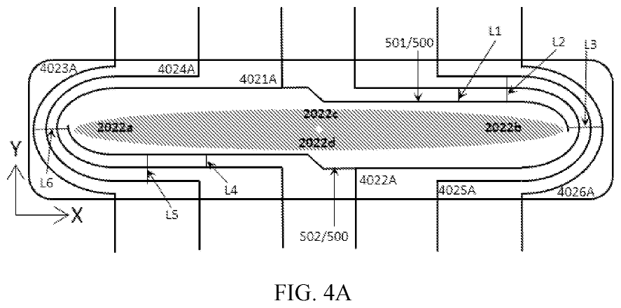

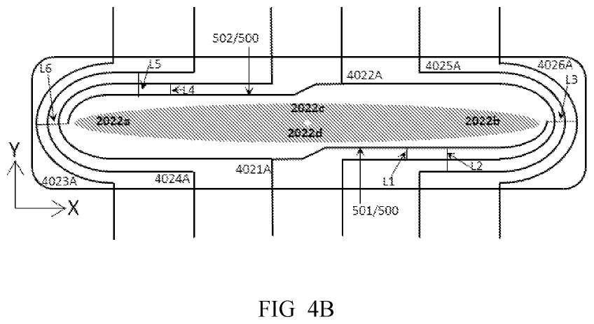

In some embodiments of the present disclosure, referring to FIG. 3A, the first connecting line 4021A includes a compensating line 500. The compensating line 500 is electrically connected to the first connecting line 4021A and is immediately adjacent to the second connecting line 4022A. In some embodiments of the present disclosure, referring to FIG. 3B, the second connecting line 4022A includes the compensating line 500. The compensating line 500 is electrically connected to the second connecting line 4022A and is immediately adjacent to the first connecting line 4021A. FIG. 4A is a partial schematic view of an array substrate according to another embodiment of the present disclosure. In still other embodiments, referring to FIG. 4A, the first connecting line 4021A and the second connecting line 4022A each include the compensating line 500. The compensating line 500 includes a first compensating line 501 and a second compensating line 502. The first compensating line 501 is electrically connected to the first connecting line 4021A. The second compensating line 502 is electrically connected to the second connecting line 4022A. The first compensating line 501 is immediately adjacent to the second connecting line 4022A. The second compensating line is immediately adjacent to the first connecting line 4021A.

According to the array substrate 000 provided by the embodiment of the present disclosure, the first connecting line 4021A and/or the second connecting line 4022A include the compensating line. The compensating line 500 of the first connecting line 4021A and/or the second connecting line 4022A is immediately adjacent to the second connecting line 4022A and/or the first connecting line 4021A. In this way, the compensating line 500 of the first connecting line 4021A and the second connecting line 4022A compensate a capacitance to each other and/or the compensating line 500 of the second connecting line 4022A and the first connecting line 4021A compensate a capacitance to each other. It is achieved that the first connecting line 4021A and the second connecting line 4022A have a same coupling capacitance as other connecting lines in the wiring region 2021, the first signal line 4021 and the second signal line 4022 have a same coupling capacitance as other signal lines in the display region 300, and a voltage signal received by the first signal line 4021 and the second signal line 4022 is the same as a voltage signal received by other signal lines in the display region 300, thereby solving the problem of the bright line in the region CC. Moreover, the compensating line may be formed with other metal layers in the array substrate 000 in a same process. This does not increase a new process, and is simple and convenient in operation.

In some embodiments of the present disclosure, the compensating line 500 and the signal line 400 are provided in a same metal layer. Referring to FIG. 3A, the compensating line 500 is connected to the first connecting line 4021A. Along the first direction X, the compensating line 500 is provided at a side of the second connecting line 4022A adjacent to the second side 2022b of the aperture 2022. Along the second direction Y, the compensating line 500 is provided at a side of the second connecting line 4022A adjacent to the third side 2022c of the aperture 2022 and extends to a side of the second connecting line 4022A adjacent to the fourth side 2022d of the aperture 2022. The compensating line 500 is immediately adjacent to the second connecting line 4022A. It may be understood that a distance L1 from the compensating line 500 to the second connecting line 4022A is smaller than a distance L2 from the compensating line 500 to the fifth connecting line 4025A, and smaller than a distance L3 from the compensating line 500 to the sixth connecting line 4026A. In the embodiments of the present disclosure, the compensating line 500 is immediately adjacent to the second connecting line 4022A. A side of the compensating line 500 overlaps with a side of the second connecting line 4022A. Hence, the compensating line 500 and the second connecting line 4022A can generate a coupling capacitance, thereby improving a capacitance of the first signal line 4021 and a capacitance of the second signal line 4022, and achieving uniform capacitances of the signal lines 400 in the display region 300.

In other embodiments of the present disclosure, as shown in FIG. 3B, the compensating line 500 is connected to the second connecting line 4022A. Along the first direction X, the compensating line 500 is provided at a side of the first connecting line 4021A adjacent to the first side 2022a of the aperture 2022. Along the second direction Y, the compensating line 500 is provided at a side of the first connecting line 4021A adjacent to the third side 2022c of the aperture 2022 and extends to a side of the first connecting line 4021A adjacent to the fourth side 2022d of the aperture 2022. A distance L4 from the compensating line 500 to the first connecting line 4021A is smaller than a distance L5 from the compensating line 500 to the fourth connecting line 4024A, and smaller than a distance L6 from the compensating line 500 to the third connecting line 4023A. In other embodiments of the present disclosure, as shown in FIG. 3C, the compensating line 500 is connected to the first connecting line 4021A. Along the first direction X, the compensating line 500 is provided at a side of the second connecting line 4022A adjacent to the second side 2022b of the aperture 2022. Along the second direction Y, the compensating line 500 is provided at a side of the second connecting line 4022A adjacent to the fourth side 2022d of the aperture 2022 and extends to a side of the first connecting line 4021A adjacent to the third side 2022c of the aperture 2022. A distance L1 from the compensating line 500 to the second connecting line 4022A is smaller than a distance L2 from the compensating line 500 to the fifth connecting line 4025A, and smaller than a distance L3 from the compensating line 500 to the sixth connecting line 4026A.

In other embodiments of the present disclosure, as shown by FIG. 3D, the compensating line 500 is connected to the second connecting line 4022A. Along the first direction X, the compensating line 500 is provided at a side of the first connecting line 4021A adjacent to the first side 2022a of the aperture 2022. Along the second direction Y, the compensating line 500 is provided at a side of the first connecting line 4021A adjacent to the fourth side 2022d of the aperture 2022 and extends to a side of the first connecting line 4021A adjacent to the third side 2022c of the aperture 2022. A distance L4 from the compensating line 500 to the first connecting line 4021A is smaller than a distance L5 from the compensating line 500 to the fourth connecting line 4024A, and smaller than a distance L6 from the compensating line 500 to the third connecting line 4023A.

In the embodiments shown in FIG. 3A to FIG. 3D, the compensating line 500 comes in direct contact and electrical connection with the first connecting line 4021A or the second connecting line 4022A. The compensating line 500, the first connecting line 4021A and the second connecting line 4022A are formed with a same mask. The compensating line 500 is as wide as other connecting lines in the wiring region 2021. In this way, the manufactured compensating line has a same fabrication error as the connecting lines, thereby facilitating calculation of the coupling capacitance. A length of the compensating line 500 is 80% to 120% of a length of the first connecting line 4021A or the second connecting line 4022A. Preferably, the length of the compensating line 500 is the same as the length of the first connecting line 4021A or the second connecting line 4022A. In this way, the compensating line 500 and the first connecting line 4021A or the second connecting line 4022A compensate the capacitance to each other to achieve uniform capacitances of the signal lines 402. Moreover, the compensating line 500 and the first connecting line 4021A or the second connecting line 4022A are provided on the same metal layer, such that perforated connection turns out to be unnecessary, and a manufacturing cost is reduced.

In some embodiments of the present disclosure, as shown in FIG. 4A, the compensating line 500 includes a first compensating line 501 and a second compensating line 502. The first compensating line 501 is immediately adjacent to the second connecting line 4022A. Along the first direction X, the first compensating line 501 is provided at a side of the second connecting line 4022A adjacent to the second side 2022b of the aperture 2022. Along the second direction Y, the first compensating line 501 is provided at a side of the second connecting line 4022A adjacent to the third side 2022c of the aperture 2022. The second compensating line 502 is immediately adjacent to the first connecting line 4021A. Along the first direction X, the second compensating line 502 is provided at a side of the first connecting line 4021A adjacent to the first side 2022a of the aperture 2022. Along the second direction Y, the second compensating line 502 is provided at a side of the first connecting line 4021A adjacent to the fourth side 2022d of the aperture 2022. In other embodiments of the present disclosure, as shown in FIG. 4B, along the first direction X, the first compensating line 501 is provided at a side of the second connecting line 4022A adjacent to the second side 2022b of the aperture 2022. Along the second direction Y, the first compensating line 501 is provided at a side of the second connecting line 4022A adjacent to the fourth side 2022d of the aperture 2022. The second compensating line 502 is immediately adjacent to the first connecting line 4021A. Along the first direction X, the second compensating line 502 is provided at a side of the first connecting line 4021A adjacent to the first side 2022a of the aperture 2022. Along the second direction Y, the second compensating line 502 is provided at a side of the first connecting line 4021A adjacent to the third side 2022c of the aperture 2022.

As shown in FIG. 4A and FIG. 4B, a distance L1 from the first compensating line 501 to the second connecting line 4022A is smaller than a distance L2 from the first compensating line 501 to the fifth connecting line 4025A, and smaller than a distance L3 from the first compensating line 501 to the sixth connecting line 4026A. A distance L4 from the second compensating line 502 to the first connecting line 4021A is smaller than a distance L5 from the second compensating line 502 to the fourth connecting line 4024A, and smaller than a distance L6 from the second compensating line 502 to the third connecting line 4023A. Meanwhile, the distance L1 from the first compensating line 501 to the second connecting line 4022A is the same as the distance L4 from the second compensating line 502 to the first connecting line 4021A. The distance L2 from the first compensating line 501 to the fifth connecting line 4025A is the same as the distance L5 from the second compensating line 502 to the fourth connecting line 4024A. The distance L3 from the first compensating line 501 to the sixth connecting line 4026A is the same as the distance L6 from the second compensating line 502 to the third connecting line 4023A. A projection of the first compensating line 501 on a plane of the base 100 and a projection of the second compensating line 502 on the plane of the base 100 are symmetric with respect to a projection of a center of the aperture 2022 on the plane of the base 100. This achieves that the array substrate 000 is etched uniformly in manufacture, and can further achieve uniform electrical performance of each signal line 402.

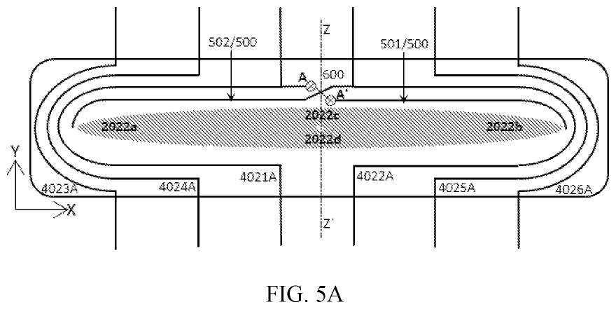

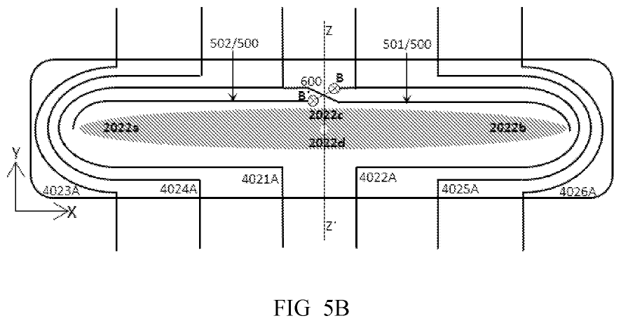

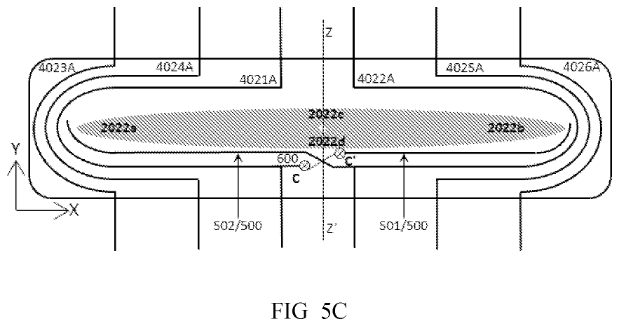

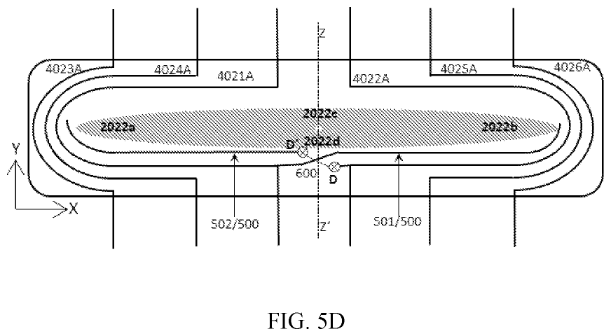

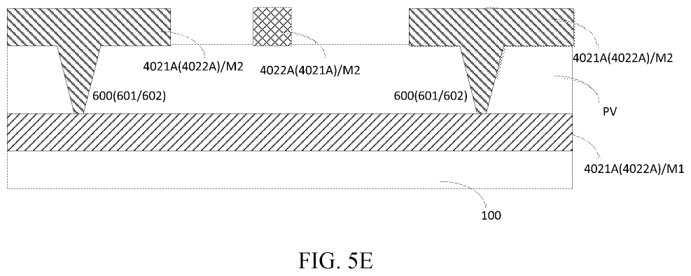

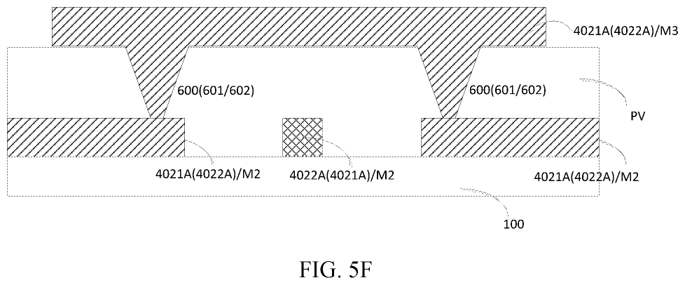

FIG. 5A is a partial schematic view of an array substrate according to another embodiment of the present disclosure. As shown in FIG. 5A, the compensating line 500 includes a first compensating line 501 and a second compensating line 502. The first connecting line 4021A comes in cross-line and electrical connection with the first compensating line 501 through a via hole 600. The second connecting line 4022A comes in direct contact and connection with the second compensating line 502. Along the first direction X, the first compensating line 501 is provided at a side of the second connecting line 4022A adjacent to the second side 2022b of the aperture 2022. The second compensating line 502 is provided at a side of the first connecting line 4021A adjacent to the first side 2022a of the aperture 2022. Along the second direction Y, the first compensating line 501 is provided at a side of the second connecting line 4022A adjacent to the third side 2022c of the aperture 2022. Likewise, the second compensating line 502 is provided at a side of the first connecting line 4021A adjacent to the third side 2022c of the aperture 2022. FIG. 5E is a schematic sectional view along a line A-A′ shown in FIG. 5A. As shown in FIG. 5E, the array substrate 000 includes the base 100, a first metal layer M1, and a second metal layer M2. An insulating layer PV is provided between the first metal layer M1 and the second metal layer M2. The first connecting line 4021A and the second connecting line 4022A are provided on the second metal layer M2. The first compensating line 501 and the second compensating line 502 are also provided on the second metal layer M2. In order to avoid a crossover short circuit between the first compensating line 501 and the second compensating line 502, the first compensating line 501 and the first connecting line 4021A come in cross-line and electrical connection on the first metal layer M1 through the via hole 600. FIG. 5F is another schematic sectional view along a line A-A′ shown in FIG. 5A. As shown in FIG. 5F, the array substrate 000 includes the base 100, a second metal layer M2, and a third metal layer M3. An insulating layer PV is provided between the second metal layer M2 and the third metal layer M3. The first connecting line 4021A and the second connecting line 4022A are provided on the second metal layer M2. The first compensating line 501 and the second compensating line 502 are also provided on the second metal layer M2. In order to avoid a crossover short circuit between the first compensating line 501 and the second compensating line 502, the first compensating line 501 and the first connecting line 4021A come in cross-line and electrical connection on the third metal layer M3 through a via hole 600. In other embodiments of the present disclosure, as shown in FIG. 5B, along the first direction X, the first compensating line 501 is provided at a side of the second connecting line 4022A adjacent to the second side 2022b of the aperture 2022. The second compensating line 502 is provided at a side of the first connecting line 4021A adjacent to the first side 2022a of the aperture 2022. Along the second direction Y, the first compensating line 501 is provided at a side of the second connecting line 4022A adjacent to the third side 2022c of the aperture 2022. Likewise, the second compensating line 502 is provided at a side of the first connecting line 4021A adjacent to the third side 2022c of the aperture 2022. The first compensating line 501 comes in direct contact and connection with the first connecting line 4021A. The second compensating line 502 is electrically connected to the second connecting line 4022A through a via hole 600. In FIG. 5B, a schematic sectional view along a line B-B′ may refer to FIG. 5E or FIG. 5F, and is not elaborated herein. In some embodiments of the present disclosure, as shown in FIG. 5C, along the first direction X, the first compensating line 501 is provided at a side of the second connecting line 4022A adjacent to the second side 2022b of the aperture 2022. The second compensating line 502 is provided at a side of the first connecting line 4021A adjacent to the first side 2022a of the aperture 2022. Along the second direction Y, the first compensating line 501 is provided at a side of the second connecting line 4022A adjacent to the fourth side 2022d of the aperture 2022. Likewise, the second compensating line 502 is provided at a side of the first connecting line 4021A adjacent to the fourth side 2022d of the aperture 2022. The first compensating line 501 is electrically connected to the first connecting line 4021A through a via hole 600. The second compensating line 502 comes in direct contact and connection with the second connecting line 4022A. In FIG. 5C, a schematic sectional view along a line C-C′ may refer to FIG. 5E or FIG. 5F, and is not elaborated herein. In some embodiments of the present disclosure, as shown in FIG. 5D, along the first direction X, the first compensating line 501 is provided at a side of the second connecting line 4022A adjacent to the second side 2022b of the aperture 2022. The second compensating line 502 is provided at a side of the first connecting line 4021A adjacent to the first side 2022a of the aperture 2022. Along the second direction Y, the first compensating line 501 is provided at a side of the second connecting line 4022A adjacent to the fourth side 2022d of the aperture 2022. Likewise, the second compensating line 502 is provided at a side of the first connecting line 4021A adjacent to the fourth side 2022d of the aperture 2022. The first compensating line 501 comes in direct contact and connection with the first connecting line 4021A. The second compensating line 502 is electrically connected to the second connecting line 4022A through a via hole 600. In FIG. 5D, a schematic sectional view along a line D-D′ may refer to FIG. 5E or FIG. 5F, and is not elaborated herein. As shown in FIGS. 5A-5D, the first compensating line 501 and the second compensating line 502 are symmetric with respect to an axis ZZ′ parallel to the second direction Y and passing through a center of the aperture 2022. Along the second direction Y, the first compensating line 501 and the second compensating line 502 are located at a same side, so as to reduce an area of the wiring region 2021. One of the first compensating line 501 and the second compensating line 502 is electrically connected to the connecting line through the via hole, and the other of the first compensating line and the second compensating line comes in direct contact and electrical connection with the connecting line. This can avoid the crossover short circuit between the first compensating line 501 and the second compensating line 502.

In the embodiments shown in FIG. 4A to FIG. 4B as well as FIG. 5A to FIG. 5B, a length of the first compensating line 501 and a length of the second compensating line 502 are the same. The length of the first compensating line 501 and the length of the second compensating line 502 each account for 30% to 70% of a length of the first connecting line 4021A or the second connecting line 4022A. Preferably, the length of the first compensating line 501 and the length of the second compensating line 502 each account for 50% of the length of the first connecting line 4021A or the second connecting line 4022A. In this way, the first compensating line 501 and the second connecting line 4022A as well as the second compensating line 502 and the first connecting line 4021A can compensate a capacitance to each other. Therefore, the first signal line 4021 and the second signal line 4022 keep the same coupling capacitance as other signal lines, thereby solving the problem of the bright line in the region CC.

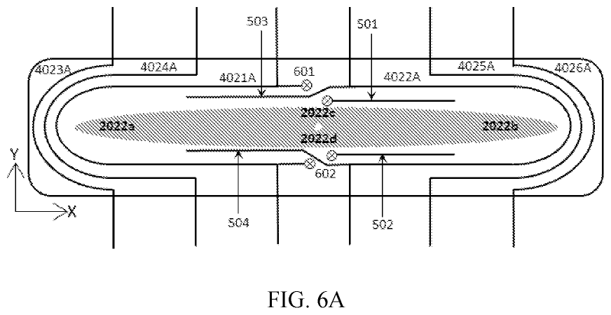

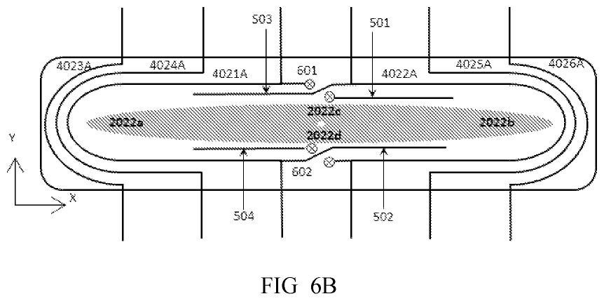

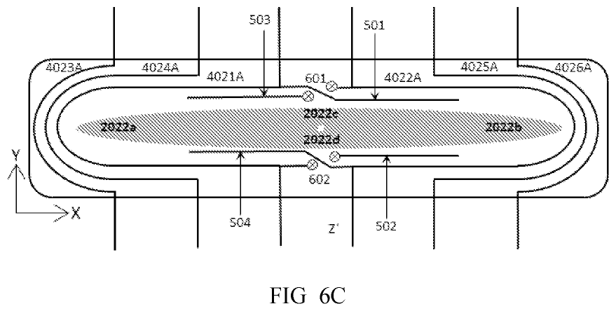

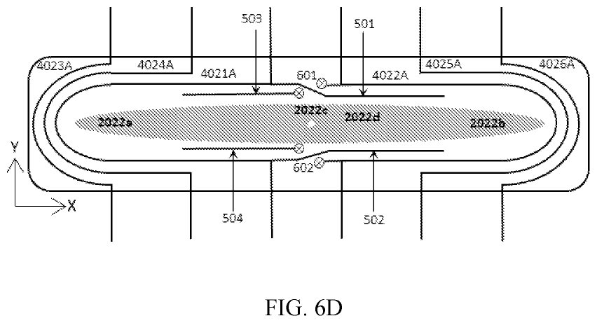

FIG. 6A is a partial schematic view of an array substrate according to another embodiment of the present disclosure. As shown in FIG. 6A, the first connecting line 4021A includes a first compensating line 501 and a second compensating line 502. The second connecting line 4022A includes a third compensating line 503 and a fourth compensating line 504. Along the first direction X, the first compensating line 501 and the second compensating line 502 are provided at a side of the second connecting line 4022A adjacent to the first side 2022a of the aperture. The third compensating line 503 and the fourth compensating line 504 are provided at a side of the first connecting line 4021A adjacent to the second side 2021b of the aperture. Along the second direction Y, the first compensating line 501 and the third compensating line 503 are respectively provided at a side of the second connecting line 4022A adjacent to the third side 2022c of the aperture 2022 and a side of the first connecting line 4021A adjacent to the third side of the aperture. The second compensating line 502 and the fourth compensating line 504 are respectively provided at a side of the second connecting line 4022A adjacent to the fourth side 2022d of the aperture 2022 and a side of the first connecting line 4021A adjacent to the fourth side of the aperture. This can further make the coupling capacitances more uniform, and make the display more uniform.

In some embodiments of the present disclosure, as shown in FIG. 6A, the first compensating line 501 is electrically connected to the first connecting line 4021A through a via hole 601. The second compensating line 502 is electrically connected to the first connecting line 4021A through a via hole 602. The third compensating line 503 comes in direct contact and electrical connection with the second connecting line 4022A. The fourth compensating line 504 comes in direct contact and electrical connection with the second connecting line 4022A. In some embodiments of the present disclosure, as shown in FIG. 6B, the first compensating line 501 is electrically connected to the first connecting line 4021A through a via hole 601. The second compensating line 502 comes in direct contact and electrical connection with the first connecting line 4021A. The third compensating line 503 comes in direct contact and electrical connection with the second connecting line 4022A. The fourth compensating line 504 is electrically connected to the second connecting line 4022A through a via hole 602. In some embodiments of the present disclosure, as shown in FIG. 6C, the first compensating line 501 comes in direct contact and electrical connection with the first connecting line 4021A. The second compensating line 502 is electrically connected to the first connecting line 4021A through a via hole 602. The third compensating line 503 is electrically connected to the second connecting line 4022A through a via hole 601. The fourth compensating line 504 comes in direct contact and electrical connection with the second connecting line 4022A. In some embodiments of the present disclosure, as shown in FIG. 6D, the first compensating line 501 comes in direct contact and electrical connection with the first connecting line 4021A. The second compensating line 502 comes in direct contact and electrical connection with the first connecting line 4021A. The third compensating line 503 is electrically connected to the second connecting line 4022A through a via hole 601. The fourth compensating line 504 is electrically connected to the second connecting line 4022A through the via hole 602. As long as there is no crossover short circuit between the first compensating hole 501 and the third compensating hole 503 as well as no crossover short circuit between the second compensating hole 502 and the fourth compensating line, the structure of the via hole 601 and the structure of the via hole 602 refer to the descriptions on FIG. 5E and FIG. 5F, and are not elaborated herein.

In the embodiments shown in FIGS. 6A-6D, a length of the first compensating line 501, a length of the second compensating line 502, a length of the third compensating line 503 and a length of the fourth compensating line 504 each account for 15% to 35% of a length of the first connecting line 4021A or the second connecting line 4022A. Preferably, the length of the first compensating line 501, the length of the second compensating line 502, the length of the third compensating line 503 and the length of the fourth compensating line 504 each account for 25% of the length of the first connecting line 4021A or the second connecting line 4022A. This can achieve uniform coupling capacitances of the connecting lines in the wiring region 2021.

In FIG. 3A to FIG. 3D, FIG. 4A to FIG. 4D, FIG. 5A to FIG. 5D and FIG. 6A to FIG. 6D, in order to keep uniform electrical signals, a width of the compensating line 500 is the same as a width of the connecting line. Moreover, in the wiring region 2021, a distance from the compensating line 500 to an immediately adjacent connecting line of the compensating line is the same as a distance between adjacent connecting lines in the wiring region (not shown in the drawing). This makes a process simpler, and an operation more convenient.

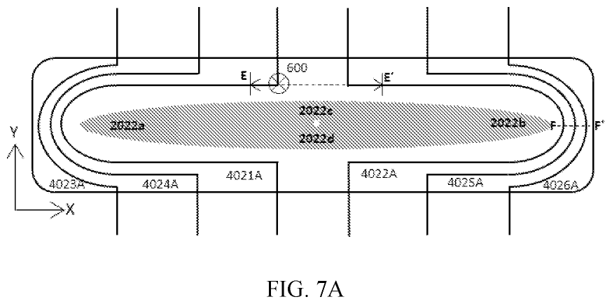

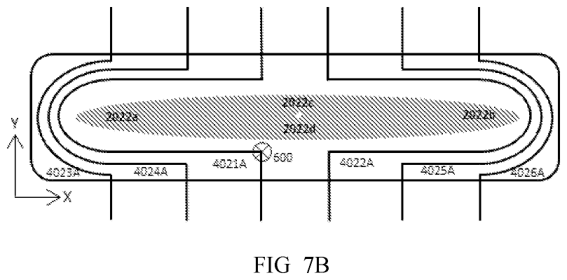

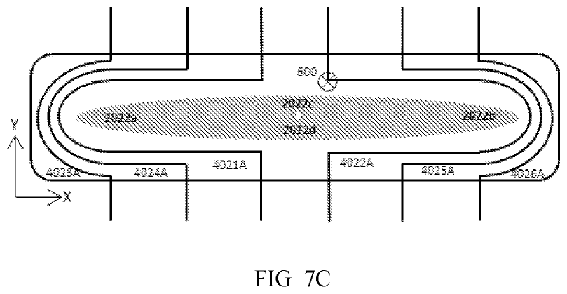

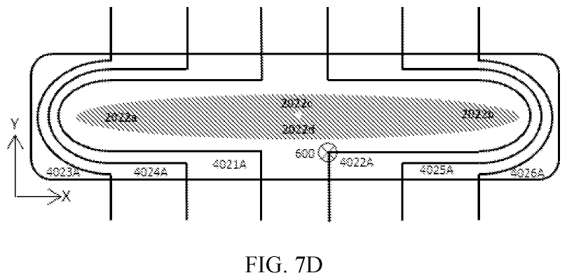

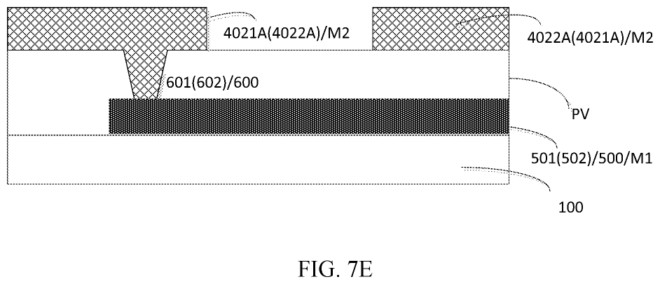

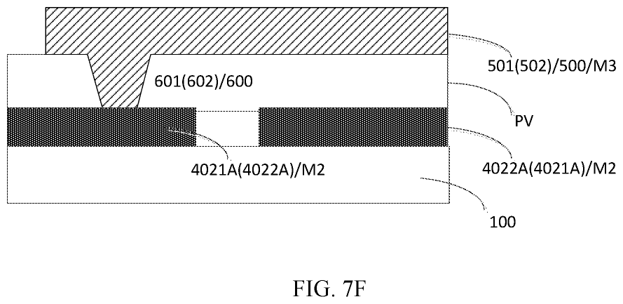

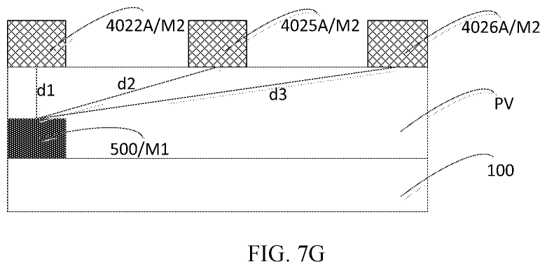

In some embodiments of the present disclosure, the array substrate 000 includes a first metal layer M1, a second metal layer M2, and a third metal layer M3. Along a direction perpendicular to the array substrate, the first metal layer M1, the second metal layer M2, and the third metal layer are stacked sequentially. The compensating line 500 and the first connecting line 4021A as well as the second connecting line 4022A are provided in different layers. FIG. 7A is a partial schematic view of an array substrate according to another embodiment of the present disclosure. FIG. 7E is a schematic sectional view along a line E-E′ shown in FIG. 7A. FIG. 7F is another schematic sectional view along a line E-E′ shown in FIG. 7A. Referring to FIG. 7A and FIG. 7E, the first connecting line 4021A includes the compensating line 500. The first connecting line 4021A and the second connecting line 4022A are provided on the second metal layer M2. The compensating line 500 is provided on the first metal layer M1. The compensating line 500 comes in cross-line connection with the first connecting line 4021A through a via hole 600. Along the first direction X, the compensating line 500 is adjacent to the second side 2022b of the aperture 2022. Along the second direction Y, the compensating line 500 is adjacent to the third side 2022c of the aperture 2022. A projection of the compensating line 500 on a plane of the base 100 overlaps with a projection of the second connecting line 4022A on the plane of the base 100. The compensating line 500 may be manufactured with a gate line in a same process. In some embodiments of the present disclosure, referring to FIG. 7F, the compensating line 500 may also be provided on the third metal layer M3. The compensating line 500 may be manufactured with a common electrode line in a same process, so as to save a cost. FIG. 7G is a schematic sectional view along a line F-F′ shown in FIG. 7A. In some embodiments of the present disclosure, referring to FIG. 7G, the compensating line 500 is immediately adjacent to the second connecting line 4022A. It may be understood that the compensating line 500 is located fittingly below or above the second connecting line 4022A (fittingly below the second connecting line in the drawing). A distance from the compensating line 500 to the second connecting line 4022A is smaller than a distance d2 from the compensating line 500 to the fifth connecting line 4025A, and smaller than a distance d3 from the compensating line 500 to the sixth connecting line. The compensating line 500 is immediately adjacent to the second connecting line 4022A. A film layer between the compensating line 500 and the second connecting line 4022A can be taken as a medium to form a coupling capacitance, such that the coupling capacitance of the compensating line 500 and the coupling capacitance of the second connecting line 4022A are increased to achieve the uniform coupling capacitances of the signal lines.

In some embodiments of the present disclosure, referring to FIG. 7B, the compensating line 500 comes in cross-line connection with the first connecting line 4021A through a via hole 600. Along the first direction X, the compensating line 500 is adjacent to the second side 2022b of the aperture 2022. Along the second direction Y, the compensating line 500 is adjacent to the fourth side 2022d of the aperture 2022. A projection of the compensating line 500 on a plane of the base 100 overlaps with a projection of the second connecting line 4022A on the plane of the base 100. In some embodiments of the present disclosure, referring to FIG. 7C, the compensating line 500 comes in cross-line connection with the second connecting line 4022A through a via hole 600. Along the first direction X, the compensating line 500 is adjacent to the first side 2022a of the aperture 2022. Along the second direction Y, the compensating line 500 is adjacent to the third side 2022c of the aperture 2022. A projection of the compensating line 500 on a plane of the base 100 overlaps with a projection of the first connecting line 4021A on the plane of the base 100. In some embodiments of the present disclosure, referring to FIG. 7D, the compensating line 500 comes in cross-line connection with the second connecting line 4022A through a via hole 600. Along the first direction X, the compensating line 500 is adjacent to the first side 2022a of the aperture 2022. Along the second direction Y, the compensating line 500 is adjacent to the fourth side 2022d of the aperture 2022. A projection of the compensating line 500 on a plane of the base 100 overlaps with a projection of the first connecting line 4021A on the plane of the base 100. The manner for connecting the compensating line 500 and the electrically connected connecting line refers to FIG. 7E or FIG. 7F, and is not elaborated herein.

It may be understood that the compensating line 500 overlaps with the first connecting line 4021A or the second connecting line 4022A in the direction perpendicular to the plane of the base. Hence, a coupling capacitance is generated between the compensating line 500 and the first connecting line 4021A or the second connecting line 4022A, a coupling capacitance of the first connecting line 4021A and a coupling capacitance of the second connecting line 4022A are increased, and a capacitance of the signal line 4021 and a capacitance of the signal line 4022 are increased, thereby solving the problem of the bright line in the region CC. In addition, since a dielectric constant & of the insulating layer PV between the compensating line 500 and the first connecting line 4021A or the second connecting line 4022A is uncertain according to different materials of the insulating layer, and the insulating layer has an uncertain thickness d, the length of the compensating line 500 can be adjusted according to a design in an actual product. On the other hand, since the compensating line 500 is provided fittingly above or below the first connecting line 4021A or the second connecting line 4022A on different metal layers in the embodiment, no new signal line is increased in the wiring region 2021. This can reduce an area of the wiring region 2021, and can reduce a border of the display panel.

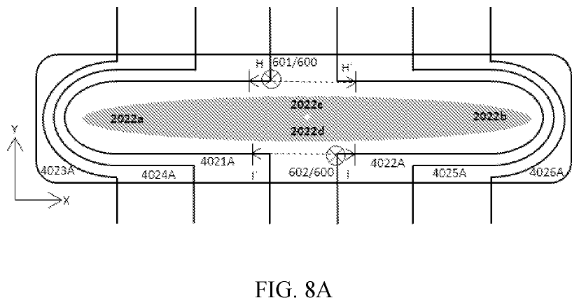

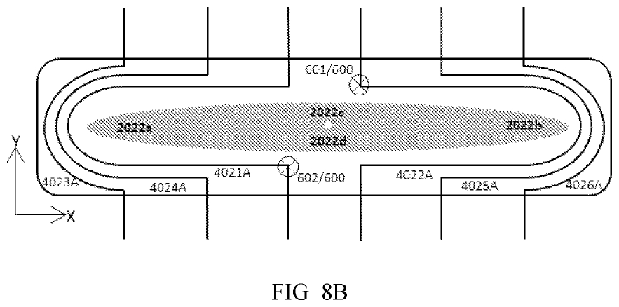

In some embodiments of the present disclosure, the compensating line 500 includes a first compensating line 501 and a second compensating line 502. FIG. 8A is a partial schematic view of an array substrate according to another embodiment of the present disclosure. In the embodiment, along the first direction X, the first compensating line 501 is adjacent to the second side 2022b of the aperture 2022, and the second compensating line 502 is adjacent to the first side 2022a of the aperture 2022. Along the second direction Y, the first compensating line 501 is adjacent to the third side 2022c of the aperture 2022, and a projection of the first compensating line 501 on a plane of the base 100 overlaps with the second connecting line 4022A. The second compensating line 502 is adjacent to the fourth side 2022d of the aperture 2022, and a projection of the second compensating line 502 on the plane of the base 100 overlaps with the first connecting line 4021A. The projection of the first compensating line 501 on the plane of the base 100 and the projection of the second compensating line 502 on the plane of the base 100 are symmetric with respect to a center of the aperture 2022. FIG. 8B is a partial schematic view of an array substrate according to another embodiment of the present disclosure. In some embodiments of the present disclosure, along the first direction X, the first compensating line 501 is adjacent to the second side 2022b of the aperture 2022, and the second compensating line 502 is adjacent to the first side 2022a of the aperture 2022. Along the second direction Y, the first compensating line 501 is adjacent to the fourth side 2022d of the aperture 2022, and a projection of the first compensating line 501 on a plane of the base 100 overlaps with the second connecting line 4022A. The second compensating line 502 is adjacent to the third side 2022c of the aperture 2022, and a projection of the second compensating line 502 on the plane of the base 100 overlaps with the first connecting line 4021A. The projection of the first compensating line 501 on the plane of the base 100 and the projection of the second compensating line 502 on the plane of the base 100 are symmetric with respect to a center of the aperture 2022.

In FIG. 8A, a schematic sectional view along a line H-H′ and a schematic sectional view along a line I-I′ may refer to FIG. 7E or FIG. 7F. In some embodiments of the present disclosure, the first compensating line 501 and the second compensating line 502 are provided on the first metal layer M1. The first connecting line 4021A and the second connecting line 4022A are provided on the second metal layer M2. The first compensating line 501 is electrically connected to the first connecting line 4021A through a via hole 601. The second compensating line 502 is electrically connected to the second connecting line 4022A through a via hole 602. In some embodiments of the present disclosure, the first compensating line 501 is provided on the first metal layer M1. The second compensating line 502 is provided on the third metal layer M3. The first connecting line 4021A and the second connecting line 4022A are provided on the second metal layer M2. The first compensating line 501 is electrically connected to the first connecting line 4021A through a via hole 601. The second compensating line 502 is electrically connected to the second connecting line 4022A through a via hole 602. In some embodiments of the present disclosure, the first compensating line 501 is provided on the third metal layer M1. The second compensating line 502 is provided on the first metal layer M3. The first connecting line 4021A and the second connecting line 4022A are provided on the second metal layer M2. The first compensating line 501 is electrically connected to the first connecting line 4021A through a via hole 601. The second compensating line 502 is electrically connected to the second connecting line 4022A through a via hole 602. In some embodiments of the present disclosure, the first compensating line 501 is provided on the third metal layer M3. The second compensating line 502 is provided on the third metal layer M3. The first connecting line 4021A and the second connecting line 4022A are provided on the second metal layer M2. The first compensating line 501 is electrically connected to the first connecting line 4021A through a via hole 601. The second compensating line 502 is electrically connected to the second connecting line 4022A through a via hole 602. This can make the first compensating line 501 and the second compensating line 502 etched uniformly in manufacture, and can further make the capacitance of the first connecting line 4021A and the capacitance of the second connecting line 4022A uniform.

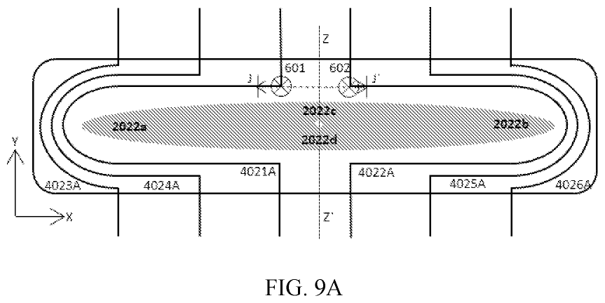

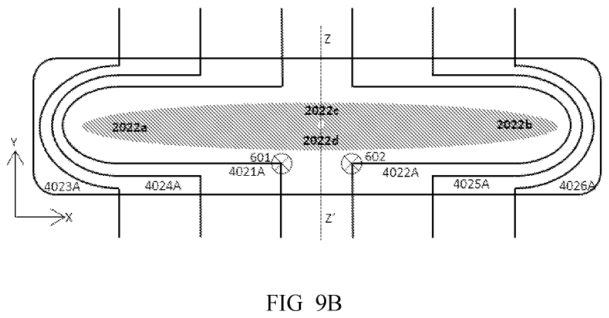

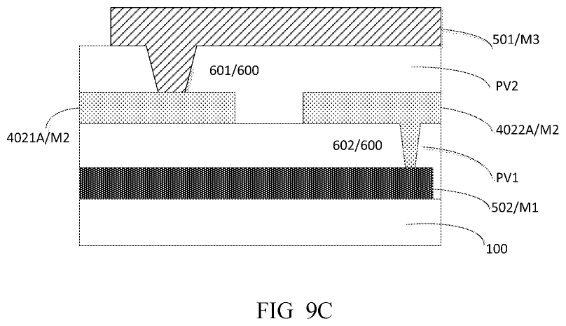

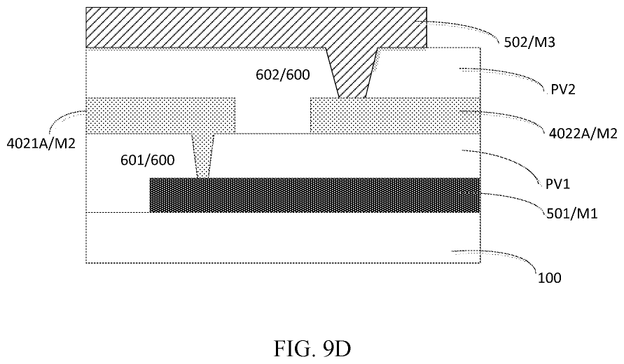

FIG. 9A is a partial schematic view of an array substrate according to another embodiment of the present disclosure. In some embodiments of the present disclosure, as shown in FIG. 9A, the first connecting line 4021A includes a first compensating line 501. The second connecting line 4022A includes a second compensating line 502. Along the first direction X, the first compensating line 501 is adjacent to the second side 2022b of the aperture 2022. The second compensating line 502 is adjacent to the first side 2022a of the aperture 2022. Along the second direction Y, both the first compensating line 501 and the second compensating line 502 are adjacent to the third side 2022c of the aperture 2022. In some embodiments of the present disclosure, as shown in FIG. 9B, the first connecting line 4021A includes a first compensating line 501. The second connecting line 4022A includes a second compensating line 502. Along the first direction X, the first compensating line 501 is adjacent to the second side 2022b of the aperture 2022. The second compensating line is adjacent to the first side 2022a of the aperture 2022. Along the second direction Y, both the first compensating line 501 and the second compensating line 502 are adjacent to the fourth side 2022d of the aperture 2022.

In FIG. 9A, a schematic sectional view along a line J-J′ may refer to FIG. 9C or FIG. 9D. In some embodiments of the present disclosure, referring to FIG. 9C, the first connecting line 4021A and the second connecting line 4022A are provided on the second metal layer M2. The first compensating line 501 is provided on the third metal layer M3. The first compensating line 501 is electrically connected to the first connecting line 4021A through a via hole 601. A projection of the first compensating line 501 on a plane of the base 100 overlaps with a projection of the second connecting line 4022A on the plane of the base 100. The second compensating line 502 is provided on the first metal layer M1. The second compensating line 502 is electrically connected to the second connecting line 4022A through a via hole 602. A projection of the second compensating line 502 on the plane of the base 100 overlaps with a projection of the first connecting line 4021A on the plane of the base 100. The projection of the first compensating line 501 on the plane of the base 100 and the projection of the second compensating line 502 on the plane of the base 100 are symmetric with respect to an axis Z-Z′ passing through a center of the aperture 2022 and parallel to the second direction Y. In some embodiments of the present disclosure, referring to FIG. 9D, the first connecting line 4021A and the second connecting line 4022A are provided on the second metal layer M2. The first compensating line 501 is provided on the first metal layer M1. The first compensating line 501 is electrically connected to the first connecting line 4021A through a via hole 601. A projection of the first compensating line 501 on a plane of the base 100 overlaps with a projection of the second connecting line 4022A on the plane of the base 100. The second compensating line 502 is provided on the third metal layer M3. The second compensating line 502 is electrically connected to the second connecting line 4022A through a via hole 602. A projection of the second compensating line 502 on the plane of the base 100 overlaps with a projection of the first connecting line 4021A on the plane of the base 100. The projection of the first compensating line 501 on the plane of the base 100 and the projection of the second compensating line 502 on the plane of the base 100 are symmetric with respect to an axis Z-Z′ passing through a center of the aperture 2022 and parallel to the second direction Y.

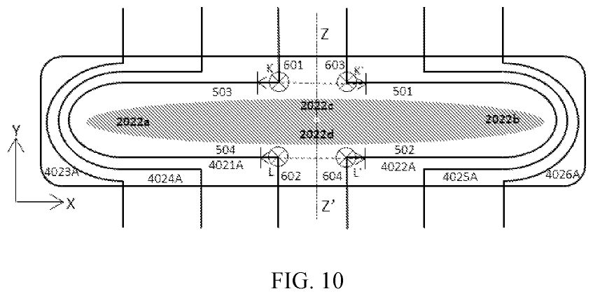

In some embodiments of the present disclosure, FIG. 10 is a partial schematic view of an array substrate according to another embodiment of the present disclosure. As shown in FIG. 10, the first connecting line 4021A includes a first compensating line 501 and a second compensating line 502. The second connecting line 4022A includes a third compensating line 503 and a fourth compensating line 504. Along the second direction Y, the first compensating line 501 and the third compensating line 503 are adjacent to the third side 2022c of the aperture 2022. The second compensating line 502 and the fourth compensating line 504 are adjacent to the fourth side 2022d of the aperture 2022. A projection of each of the first compensating line 501 and the second compensating line 502 on a plane of the base 100 overlaps with the second connecting line 4022A. A projection of each of the third compensating line 503 and the fourth compensating line 504 on the plane of the base 100 overlaps with the first connecting line 4021A. The projection of the first compensating line 501 on the plane of the base 100 and the projection of the third compensating line 503 on the plane of the base 100 are symmetric with respect to an axis Z-Z′ passing through a center of the aperture 2022 and parallel to the second direction Y. The projection of the second compensating line 502 on the plane of the base 100 and the projection of the fourth compensating line 504 on the plane of the base 100 are symmetric with respect to the axis Z-Z′ passing through the center of the aperture 2022 and parallel to the second direction Y. The projection of the first compensating line 501 on the plane of the base 100 and the projection of the fourth compensating line 504 on the plane of the base 100 are symmetric with respect to a projection of the center of the aperture 2022 on the plane of the base 100. The projection of the second compensating line 502 on the plane of the base 100 and the projection of the fourth compensating line 504 on the plane of the base 100 are symmetric with respect to the projection of the center of the aperture 2022 on the plane of the base 100.

In FIG. 10, a schematic sectional view along a line K-K′ and a schematic sectional view along a line L-L′ may refer to FIG. 9C and FIG. 9D, which are not elaborated herein, as long as the first compensating line 501 and the third compensating line 503 are provided in different layers, the second compensating line 504 and the fourth compensating line 504 are provided in different layers, and a crossover short circuit between the first compensating line 501 and the second compensating line 502 as well as between the third compensating line 503 and the fourth compensating line 504 is avoided.

In the embodiments provided by the present disclosure, the signal lines with two compensating lines have a same topological structure, and each include the connecting line and the compensating line, such that the structure is more symmetric, and the compensating effect is more uniform. The signal lines with multiple compensating lines also have a same topological structure, with a compensated trace shortened compared with the signal line with a single compensating line and the signal line with two compensating lines. This reduces influences of an impedance of the compensating line on a load of the compensated line, thereby avoiding secondary abnormal visual effect.

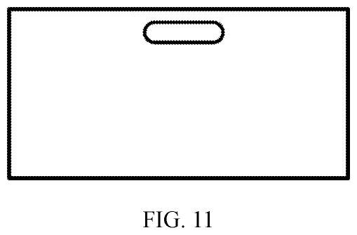

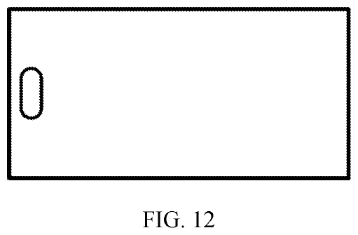

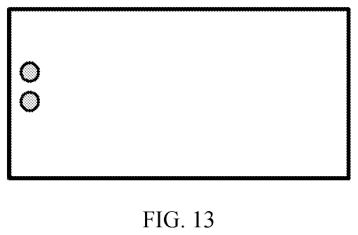

Based on a same inventive concept, embodiments of the present disclosure further provides a display panel, and a display apparatus. FIG. 11, FIG. 12 and FIG. 13 each are a schematic view of a display apparatus according to an embodiment of the present disclosure. As shown in FIG. 11, FIG. 12 and FIG. 13, the display apparatus includes the array substrate provided in any embodiment of the present disclosure. The structure of the array substrate has been described in the foregoing embodiments, and details are not elaborated herein again. The display apparatus provided by the embodiment of the present disclosure may be an electronic device such as a mobile phone, a tablet computer, a television, a computer, a car monitor and an intelligent wearable product.

The above description of the disclosed embodiments enables those skilled in the art to achieve or use the present disclosure. Various modifications to these embodiments are readily apparent to those skilled in the art, and the generic principles defined herein may be practiced in other embodiments without departing from the spirit or scope of the present disclosure. Accordingly, the present disclosure will not be limited to these examples shown herein, but is to fall within the widest scope consistent with the principles and novel features disclosed herein.

What is claimed is:

1. An array substrate, comprising:
a base, wherein the base comprises a non-display region and a display region; the non-display region comprises a first non-display region and a second non-display region; the first non-display region surrounds the display region; the display region surrounds the second non-display region; the second non-display region comprises a wiring region and an aperture; the wiring region surrounds the aperture; and the display region surrounds the wiring region;
the aperture comprises a first side and a second side opposite to each other along a first direction, and a third side and a fourth side opposite to each other along a second direction; and the first direction intersects with the second direction; and
the wiring region comprises a plurality of signal lines; one of the plurality of signal lines comprises connecting lines surrounding an edge of the aperture; the plurality of signal lines comprises first signal lines and second signal lines; the first signal line comprises a first connecting line; the second signal line comprises a second connecting line; and along the first direction, the first connecting line is adjacent to the first side, and the second connecting line is adjacent to the second side,
wherein the first connecting line and/or the second connecting line comprise a compensating line; and the compensating line of the first connecting line is immediately adjacent to the second connecting line, and/or the compensating line of the second connecting line is immediately adjacent to the first connecting line.

2. The array substrate according to claim 1, wherein the compensating line and the connecting line are provided in a same layer.

3. The array substrate according to claim 2, wherein the first connecting line or the second connecting line comprises the compensating line; and along the first direction, the compensating line is provided at a side of the second connecting line adjacent to the second side or the compensating line is provided at a side of the first connecting line adjacent to the first side.

4. The array substrate according to claim 2, wherein the first connecting line and the second connecting line each comprise the compensating line; the first connecting line comprises a first compensating line; the second connecting line comprises a second compensating line; and along the first direction, the first compensating line is provided at a side of the second connecting line adjacent to the second side, and the second compensating line is provided at a side of the first connecting line adjacent to the first side.

5. The array substrate according to claim 4, wherein along the second direction, the first compensating line is provided at a side of the second connecting line adjacent to the third side, the second compensating line is provided at a side of the first connecting line adjacent to the fourth side, and a projection of the first compensating line on a plane of the base and a projection of the second compensating line on the plane of the base are symmetric with respect to a projection of a center of the aperture on the plane of the base; or
along the second direction, the first compensating line is provided at a side of the second connecting line adjacent to the fourth side, the second compensating line is provided at a side of the first connecting line adjacent to the third side, and the projection of the first compensating line on the plane of the base and the projection of the second compensating line on the plane of the base are symmetric with respect to the projection of the center of the aperture on the plane of the base.

6. The array substrate according to claim 4, wherein along the second direction, the first compensating line and the second compensating line are respectively provided at a side of the second connecting line adjacent to the third side and a side of the first connecting line adjacent to the third side, or respectively provided at a side of the second connecting line adjacent to the fourth side and a side of the first connecting line adjacent to the fourth side; and a projection of the first compensating line on a plane of the base and a projection of the second compensating line on the plane of the base are symmetric with respect to a projection of an axis parallel to the second direction and passing through a center of the aperture on the plane of the base.

7. The array substrate according to claim 2, wherein the first connecting line and the second connecting line each comprise the compensating line; and the compensating line comprises a first compensating line, a second compensating line, a third compensating line, and a fourth compensating line;
the first connecting line comprises the first compensating line and the second compensating line; and the second connecting line comprises the third compensating line and the fourth compensating line;
along the first direction, the first compensating line and the second compensating line are provided at a side of the second connecting line adjacent to the second side; and the third compensating line and the fourth compensating line are provided at a side of the first connecting line adjacent to the first side; and
along the second direction, the first compensating line and the third compensating line are respectively provided at a side of the second connecting line adjacent to the third side and a side of the first connecting line adjacent to the third side; and the second compensating line and the fourth compensating line are respectively provided at a side of the second connecting line adjacent to the fourth side and a side of the first connecting line adjacent to the fourth side.

8. The array substrate according to claim 6, wherein the first compensating line is connected to the first connecting line through a via hole, or the second compensating line is connected to the second connecting line through a via hole.

9. The array substrate according to claim 7, wherein the first compensating line is electrically connected to the first connecting line through a via hole, and the third compensating line comes in direct contact and connection with the second connecting line; or the first compensating line comes in direct contact and connection with the first connecting line, and the third compensating line is electrically connected to the second connecting line through a via hole; and
the second compensating line is electrically connected to the first connecting line through a via hole, and the fourth compensating line comes in direct contact and connection with the second connecting line; or the second compensating line comes in direct contact and connection with the first connecting line, and the fourth compensating line is electrically connected to the second connecting line through a via hole.

10. The array substrate according to claim 2, wherein a width of the compensating line is the same as a width of the connecting line; or
wherein a distance from the compensating line to an adjacent connecting line of the compensating line is the same as a distance between adjacent connecting lines.

11. The array substrate according to claim 1, wherein the compensating line and the signal line are provided in different layers; and along a direction perpendicular to the array substrate, a first metal layer, a second metal layer, and a third metal layer are stacked.

12. The array substrate according to claim 11, wherein the first connecting line or the second connecting line comprises the compensating line; the first connecting line and the second connecting line are provided on the second metal layer; the compensating line is provided on the first metal layer or the third metal layer; and a projection of the compensating line on a plane of the base overlaps with a projection of the second connecting line or the first connecting line on the plane of the base.

13. The array substrate according to claim 11, wherein the compensating line comprises a first compensating line and a second compensating line; the first connecting line comprises the first compensating line; and the second connecting line comprises the second compensating line.

14. The array substrate according to claim 13, wherein along the second direction, the first compensating line is adjacent to the third side; a projection of the first compensating line on a plane of the base overlaps with a projection of the second connecting line on the plane of the base; the second compensating line is adjacent to the fourth side; and a projection of the second compensating line on the plane of the base overlaps with a projection of the first connecting line on the plane of the base; or
the first compensating line is adjacent to the fourth side; the projection of the first compensating line on the plane of the base overlaps with the projection of the second connecting line on the plane of the base; the second compensating line is adjacent to the third side; and the projection of the second compensating line on the plane of the base overlaps with the projection of the first connecting line on the plane of the base.

15. The array substrate according to claim 14, wherein the connecting lines are provided on the second metal layer; and the first compensating line and the second compensating line are provided on the first metal layer or the third metal layer; or
wherein the projection of the first compensating line on the plane of the base and the projection of the second compensating line on the plane of the base are symmetric with respect to a projection of a center of the aperture on the plane of the base.

16. The array substrate according to claim 13, wherein the connecting line is provided on the second metal layer; the first compensating line is provided on the first metal layer and the second compensating line is provided on the third metal layer; or the first connecting line is provided on the third metal layer and the second compensating line is provided on the first metal layer; or
wherein a projection of the first compensating line on a plane of the base and a projection of the second compensating line on the plane of the base are symmetric with respect to a projection of an axis parallel to the second direction and passing through a center of the aperture on the plane of the base.

17. The array substrate according to claim 11, wherein the first connecting line and the second connecting line each comprise the compensating line; and the compensating line comprises a first compensating line, a second compensating line, a third compensating line, and a fourth compensating line;
the first connecting line comprises the first compensating line and the second compensating line; the second connecting line comprises the third compensating line and the fourth compensating line; the first connecting line and the second connecting line are provided on the second metal layer; and along the first direction, the first compensating line and the second compensating line are provided at a side adjacent to the second side, and the third compensating line and the fourth compensating line are provided at a side adjacent to the first side; and
along the second direction, the first compensating line and the third compensating line are provided at a side adjacent to the third side; and the second compensating line and the fourth compensating line are provided at a side adjacent to the fourth side.

18. The array substrate according to claim 17, wherein the first compensating line, the second compensating line, the third compensating line and the fourth compensating line satisfy one of following conditions:
the first compensating line and the third compensating line are provided on the first metal layer or the third metal layer, and the second compensating line and the fourth compensating line are provided on the first metal layer or the third metal layer; or
a projection of the first compensating line on a plane of the base and a projection of the third compensating line on the plane of the base are symmetric with respect to a projection of an axis parallel to the second direction and passing through a center of the aperture on the plane of the base; a projection of the second compensating line on the plane of the base and a projection of the fourth compensating line on the plane of the base are symmetric with respect to the projection of the axis parallel to the second direction and passing through the center of the aperture on the plane of the base; the projection of the first compensating line on the plane of the base and the projection of the fourth compensating line on the plane of the base are symmetric with respect to projection of the center of the aperture on the plane of the base; and the projection of the second compensating line on the plane of the base and the projection of the third compensating line on the plane of the base are symmetric with respect to the projection of the center of the aperture on the plane of the base.

19. The array substrate according to claim 1, wherein the first connecting line and the compensating line connected thereto are connected through a via hole, and/or the second connecting line and the compensating line connected thereto are connected through a via hole.

20. A display apparatus, comprising a display panel, wherein the display panel comprises an array substrate,
the array substrate comprises:
a base, wherein the base comprises a non-display region and a display region; the non-display region comprises a first non-display region and a second non-display region; the first non-display region surrounds the display region; the display region surrounds the second non-display region; the second non-display region comprises a wiring region and an aperture; the wiring region surrounds the aperture; and the display region surrounds the wiring region;
the aperture comprises a first side and a second side opposite to each other along a first direction, and a third side and a fourth side opposite to each other along a second direction; and the first direction intersects with the second direction; and
the wiring region comprises a plurality of signal lines; one of the plurality of signal lines comprises connecting lines surrounding an edge of the aperture; the plurality of signal lines comprises first signal lines and second signal lines; the first signal line comprises a first connecting line; the second signal line comprises a second connecting line; and along the first direction, the first connecting line is adjacent to the first side, and the second connecting line is adjacent to the second side,
wherein the first connecting line and/or the second connecting line comprise a compensating line; and the compensating line of the first connecting line is immediately adjacent to the second connecting line, and/or the compensating line of the second connecting line is immediately adjacent to the first connecting line.
